(19) United States
(12) Patent Application Publication
(10) Pub. No.: US 2018/0203067 A1
(43) Pub. Date: Jul. 19, 2018

(54) CLOCK GATING CIRCUITS AND SCAN CHAIN CIRCUITS USING THE SAME

(71) Applicant: MEDIATEK INC., Hsin-Chu (TW)

(72) Inventor: Yiwei CHEN, Hsin-Chu (TW)

(21) Appl. No.: 15/692,048

(22) Filed: Aug. 31, 2017

Related U.S. Application Data
(60) Provisional application No. 62/445,822, filed on Jan. 13, 2017.

(51) Int. Cl. G01R 31/3185; G11C 29/32; G01R 31/317; G01R 31/3177

(52) U.S. Cl. CPC G01R 31/318536; G11C 29/32; G01R 31/31858; G01R 31/318541; G01R 31/31727; G01R 31/3177; G01R 31/31723

(57) ABSTRACT

A scan chain circuit is provided. The scan chain circuit includes first and second scan flip-flops and a clock generator. Each of the first and second scan flip-flops has a data-in terminal, a scan-in terminal, a clock terminal, and a data-out terminal. The clock terminals of the first and second scan flip-flop receive first and second clock signals respectively. The data-in terminal of the second scan flip-flop is coupled to the data-out terminal of the first scan flip-flop. During a scan shift cycle of the test mode, an enable pulse of a second clock-enable signal is delayed from an enable pulse of a first clock-enable signal, and the clock generator generates the first clock signal according to the scan clock signal and the first clock-enable signal and further generates the second clock signal according to the scan clock signal and the second clock-enable signal.

### CROSS REFERENCE TO RELATED APPLICATIONS

This application claims the benefit of U.S. Provisional Application No. 62/445,822, filed on Jan. 13, 2017, the contents of which are incorporated herein by reference.

### BACKGROUND OF THE INVENTION

### Field of the Invention

The invention relates to a scan chain circuit, and more particularly, to a clock gating circuit applied to a scan chain circuit.

### Description of the Related Art

For integrated circuit, scan chains are applied to detect various manufacturing faults in combinatorial logic blocks during test procedures. Generally, a scan chain is composed of several scan flip-flops which are coupled in series. Combinatorial logic blocks can be tested by repeating a shift cycle followed by a capture cycle in a test mode of a scan chain. During a shift cycle, all of the scan flip-flops are activated simultaneously by the same clock signal to operate according to respective test signals, which induce a high peak current resulting in damage of the integrated circuit.

### BRIEF SUMMARY OF THE INVENTION

One exemplary embodiment of a scan chain circuit is provided. The scan chain circuit comprises a first scan flip-flop, a second scan flip-flop, and a clock generator. The first scan flip-flop has a data-in terminal, a scan-in terminal, a clock terminal receiving a first clock signal, and a data-out terminal. The second scan flip-flop has a data-in terminal coupled to the data-out terminal of the first scan flip-flop, a scan-in terminal, a clock terminal receiving a second clock signal, and a data-out terminal. The clock generator receives a function clock signal, a scan clock signal, a first clock-enable signal, a second clock-enable signal, and a test-enable signal indicating whether the scan chain circuit is in a test mode. In a scan shift cycle of the test mode, an enable pulse of the second clock-enable signal is delayed from an enable pulse of the first clock-enable signal, and the clock generator generates the first clock signal according to the scan clock signal and the first clock-enable signal and further generates the second clock signal according to the scan clock signal and the second clock-enable signal.

Another exemplary embodiment of a scan chain circuit is provided. The scan chain circuit comprises a multiplexer, a first clock gating circuit, a second clock gating circuit, a first scan flip-flop, and a second scan flip-flop. The multiplexer has a first input terminal receiving a function clock signal, a second input terminal receiving a scan clock signal and controlled by a test-enable signal to transmit the function clock signal or the scan clock signal to serve as a reference clock signal. The test-enable signal indicates whether the scan chain circuit is in a test mode. The first clock gating circuit has a clock-in terminal receiving the reference clock signal, a clock-enable terminal receiving a first clock-enable signal, a gating enable terminal receiving a first gating enable signal, and a test-enable terminal receiving the test-enable signal, and a clock-out terminal outputting a first clock signal. The second clock gating circuit has a clock-in terminal receiving the reference clock signal, a clock-enable terminal receiving a second clock-enable signal, a gating enable terminal receiving a second gating enable signal, and a test-enable terminal receiving the test-enable signal, and a clock-out terminal outputting a second clock signal. The first scan flip-flop has a data-in terminal, a scan-in terminal, a clock terminal receiving the first clock signal, and a data-out terminal. The second scan flip-flop has a data-in terminal coupled to the data-out terminal of the first scan flip-flop, a scan-in terminal, a clock terminal receiving the second clock signal, and a data-out terminal.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 shows an exemplary embodiment of a scan chain circuit;

FIG. 2 shows an exemplary embodiment of a clock generator;

FIG. 3 is a schematic view showing timing chart of clock signals and clock-enable signals according to an exemplary embodiment;

FIG. 4 shows one exemplary embodiment of a clock gating circuit;

FIG. 5 is a schematic view showing timing chart of main signals of a clock gating circuit according to an exemplary embodiment; and

FIG. 6 shows one exemplary embodiment of a clock gating circuit.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

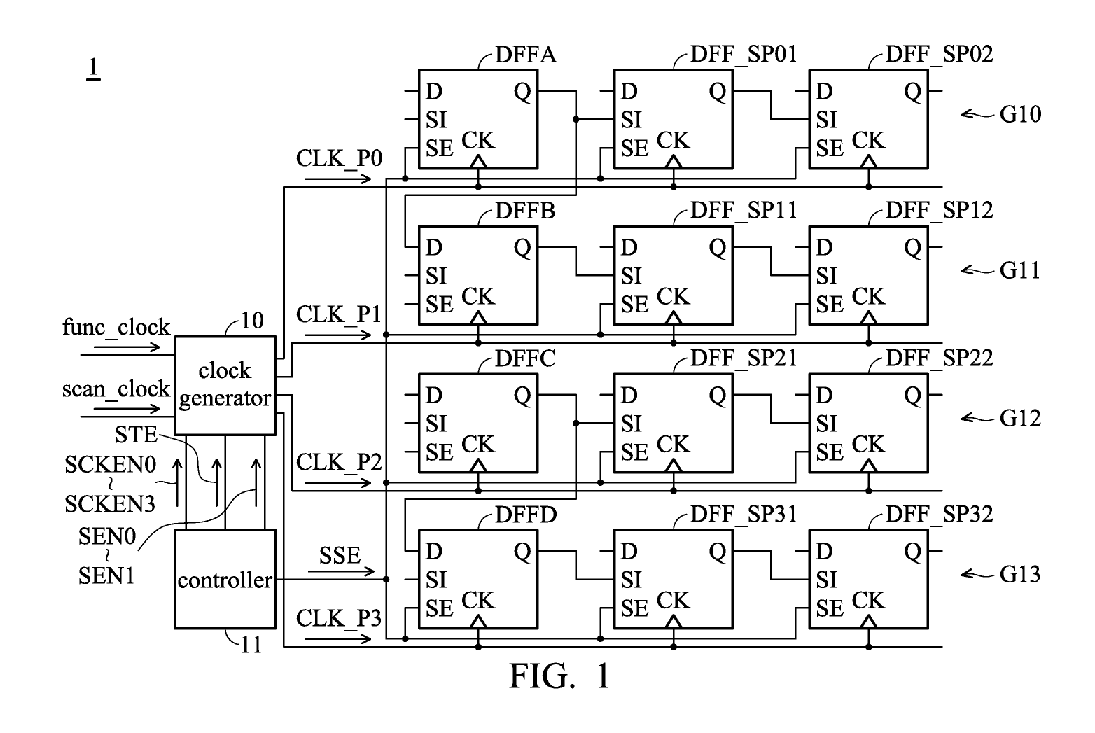

FIG. 1 shows an exemplary embodiment of a scan chain circuit to reduce peak power during testing. As shown in FIG. 1, a scan chain circuit 1 comprises a clock generator 10, a controller 11, and a plurality scan groups G10˜G13. The scan chain circuit 1 can operate in a function mode or a test mode. When the scan chain circuit 1 is in the test mode, combinatorial logic blocks coupled to the scan chain circuit 1 can be tested by repeating a shift cycle followed by a capture cycle in a test mode. Each scan group comprises a plurality of scan flip-flops which are coupled in series. In the embodiment, four scan groups G10˜G13 are taken as an example, and each scan group comprises three scan flip-flops. For example, there are three scan flip-flops DFFA, DFF_SP01, and DFF_SP02 in the scan group G10, there are three scan flip-flops DFFB, DFF_SP11, and DFF_SP12 in the scan group G11, there are three scan flip-flops DFFC, DFF_SP21, and DFF_SP22 in the scan group G12, and there are three scan flip-flops DFFD, DFF_SP31, and DFF_SP32 in the scan group G13. Each of the scan flip-flops has a data-in terminal D, a scan-in terminal SI, a scan-enable terminal SE, a clock terminal CK, and a data-out terminal Q. The clock terminals CK of the scan flip-flops in the same scan group receive the same clock signal generated by the clock generator 10. In details, the clock terminals CK of the scan flip-flops DFFA, DFF_SP01, and DFF_SP02 in the scan group G10 receive a clock signal CKL_P0; the clock terminals CK of the scan flip-flops DFFB, DFF_SP11, and DFF_S12 in the scan group G11 receive a clock signal CKL_P1; the clock terminals CK of the scan flip-flops DFFC, DFF_SP21, and DFF_S22 in the scan group G12 receive a clock signal CKL_P2; the clock terminals CK of the scan flip-flops DFFD, DFF_SP31, and DFF_S32 in the scan group G13 receive a clock signal CKL_P3.

As shown in FIG. 1, in the same scan group, the scan-in terminal SI of one scan flip-flop is coupled to the data-out terminal Q of the previous scan flip-flop for forming one scan path for the scan group. For example, in the scan group G10, the scan-in terminal SI of the first scan flip-flop DFF_SP01 is coupled to the data-out terminal Q of the scan flip-flop DFFA, and the scan-in terminal SI of the scan flip-flop DFF_SP02 is coupled to the data-out terminal Q of the scan flip-flop DFF_SP01, so that one scan path passing through the scan flip-flops DFFA, DFF_SP01, and DFF_SP02 are formed for the scan group G10. In the embodiment, since there are four scan groups G10˜G13, four scan paths are formed for the scan groups G10˜G13 respectively. Moreover, for one scan flip-flop in one scan group, the data-in terminal D is coupled to the data-out terminal Q of one scan flip-flop in another scan group for forming a function path. For example, the data-in terminal D of the scan flip-flop DFFB in the scan group G11 is coupled to the data-out terminal Q of the scan flip-flop DFFA in another scan group G10. According to the disclosed connection structure between the scan flip-flops, one scan path is formed by the scan flip-flops which belong to the same scan group and receive the same clock signal, while one function path is formed by at least two flop-flops which belong to different scan groups and receive the different scan clock phase signals. In an embodiment, the scan-in terminal SI of the first one among the scan flip-flops in one scan group, such as the scan flip-flop DFFA in the scan group G10, receives a test-in signal for the test mode of the scan chain circuit 1. Moreover, in another embodiment, the data-in terminal D of the first scan flip-flop in one function path, such as the data-in terminal D of the scan flip-flop DFFA, receives a functional data signal for the function mode of the scan chain circuit 1.

According to the embodiment, for each scan flip-flop, the scan-enable terminal SE receives a scan-enable signal SSE indicating which one of the corresponding scan path and the corresponding function path is available. For example, when the scan-enable signal SSE indicates the corresponding scan path is available (for example, when the scan chain circuit 1 is in one scan shift cycle of the test mode), the scan flip-flop operates according to the signal at its scan-in terminal SI; when the scan-enable signal SSE indicates the corresponding function path is available (for example, when the scan chain circuit 1 is in the function mode or one scan capture cycle of the test mode), the scan flip-flop operates according to the signal at its data-in terminal D. The scan-enable signal SSE is generated by the controller 11 according to the operation timing of the scan chain circuit 1.

Referring to FIG. 1, the clock generator 10 receives a function clock signal func_clock for a function mode, a scan clock signal scan_clock for a test mode, clock-enable signals SCKEN0˜SCKEN3, a test-enable signal STE, and gating enable signals SEN0˜SEN3. The test-enable signal STE is used to indicate whether the scan chain circuit 1 is in test mode or the function mode. The gating enable signals SEN0˜SEN3 are used to indicate whether clock gating operations for scan groups G10˜G13 are enabled, respectively. When the scan chain circuit 1 is in the test mode, the clock generator generates the clock signals CLK_P0˜CLK_P3 according to the scan clock signal scan_clock, the test-enable signal STE, the clock-enable signals SCKEN0˜SCKEN3, and the gating enable signals SEN0˜SEN3. When the scan chain circuit 1 is in the function mode, the clock generator 10 generates the clock signals CLK_P0˜CLK_P3 according to the function clock signal function_clock, the test-enable signal STE, the clock-enable signals SCKEN0˜SCKEN3, and the gating enable signals SEN0˜SEN3. The signals for the clock generator 10, such as the clock-enable signals SCKEN0˜SCKEN3, the test-enable signal STE, and the gating enable signals SEN0˜SEN3 are generated by the controller 11 according to the operation timing of the scan chain circuit 1. How the clock generator 10 generates the clock signals CLK_P0˜CLK_P3 will be described in the later paragraphs.

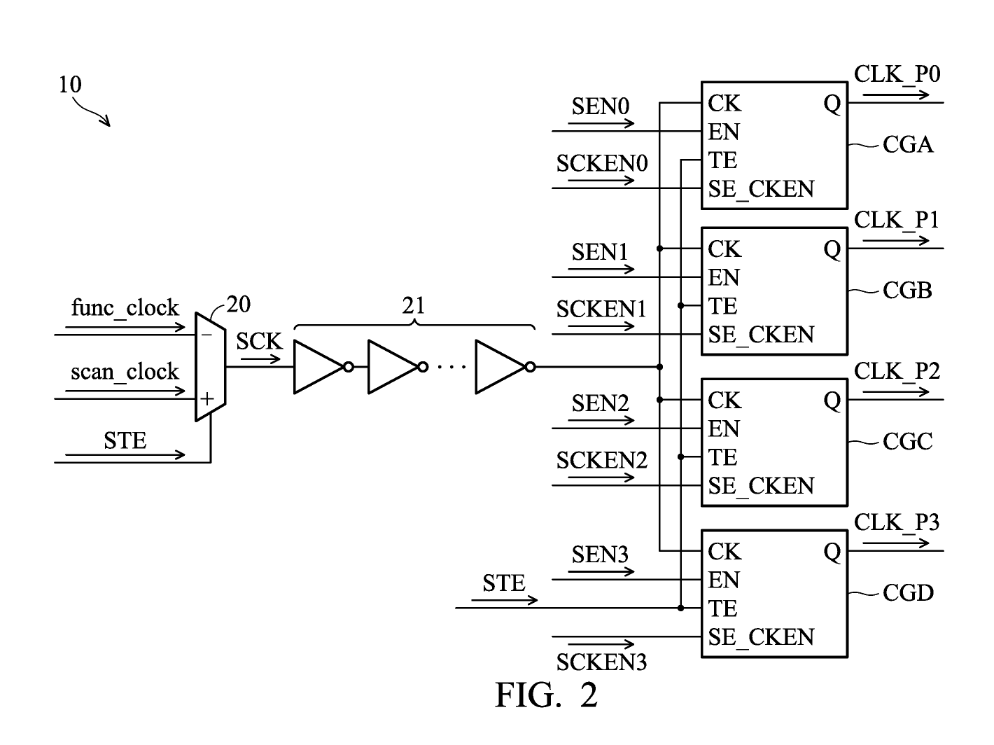

Referring to FIG. 2, the clock generator 10 comprises a multiplexer 20, a plurality of buffers 21, and a plurality of clock gating circuits for generating the clock signals to the scan groups. As described above, there are four scan groups G10˜G13, and, thus, the clock generator 10 comprises four clock gating circuits CGA˜CGD which generate the clock signals CLK_P0˜CLK_P3 for the scan groups G10˜G13 respectively. The multiplexer 20 has two input terminals receiving the function_clock signal func_clock and the scan clock signal scan_clock and an output terminal outputting a reference clock signal SCK. The multiplexer 20 is controlled by the test-enable signal STE and selectively transmits the function_clock signal func_clock or the scan clock signal scan_clock to serve as the reference clock signal SCK. When the test-enable signal STE is at a high voltage level to indicate that the scan chain circuit 1 is in the test mode, the multiplexer 20 transmits the scan clock signal scan_clock to serve as the reference clock signal SCK. When the test-enable signal STE is at a low voltage level to indicate that the scan chain circuit 1 is in the function mode, the multiplexer 20 transmits the function_clock signal func_clock to serve as the reference clock signal SCK. The reference clock signal SCK is provided to the clock gating circuits CGA˜CGD through the buffers 21.

Referring to FIG. 2, each of the clock gating circuits CGA˜CGD has a clock-in terminal CK, a clock enable terminal SE_CKEN, a gating enable terminal EN, and a test-enable terminal TE, and a clock-out terminal Q. The clock-in terminals CK of all the clock gating circuits CGA˜CGD receive the reference clock signal SCK transmitted from the multiplexer 20, and the test-enable terminals TE of all the clock gating circuits CGA˜CGD receives the test-enable signal STE. For each clock gating circuit, the gating enable terminal EN receives the corresponding gating enable terminal, and the clock-enable terminal SE_CKEN receives the corresponding clock-enable signal. In details, the gating enable terminal EN of the clock gating circuit CGA receives the gating enable signal SEN0, and the clock-enable terminal SE_CKEN thereof receives the clock-enable signal SCKEN0; the gating enable terminal EN of the clock gating circuit CGB receives the gating enable signal SEN1, and the clock-enable terminal SE_CKEN thereof receives the clock-enable signal SCKEN1; the gating enable terminal EN of the clock gating circuit CGC receives the gating enable signal SEN2, and the clock-enable terminal SE_CKEN thereof receives the clock-enable signal SCKEN2; the gating enable terminal EN of the clock gating circuit CGD receives the gating enable signal SEN3, and the clock-enable terminal SE_CKEN thereof receives the clock-enable signal SCKEN3. The clock gating circuits CGA˜CGD generate the clock signals CLK_P0˜CLK_3 for the scan groups G10˜G13 respectively.

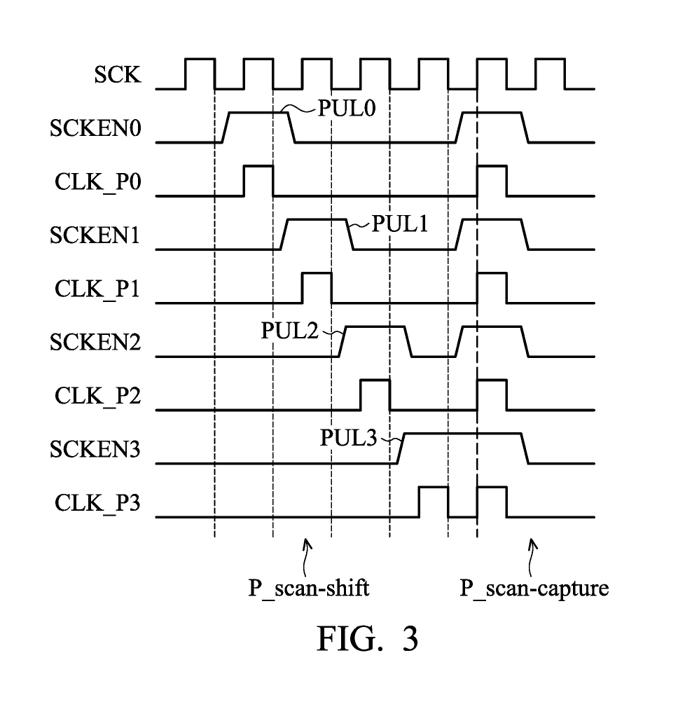

As shown in FIG. 3, the timing of the clock signals CLK_P0˜CLK_P3 and the clock-enable signals SCKEN0˜SCKEN3 is shown, In the embodiment, during each scan shift cycle P_scan-shift of the test mode, each of the clock-enable signals SCKEN0˜SCKEN3 has a full enable pulse for the operation of the shift cycle, and the full enable pulses of the clock-enable signals SCKEN0˜SCKEN occur successively. In details, the full enable pulse PUL1 of the clock-enable signal SCKEN1 is delayed from the full enable pulse PUL0 of the clock-enable signal SCKEN0, the full enable pulse PUL2 of the clock-enable signal SCKEN2 is delayed from the full enable pulse PUL1 of the clock-enable signal SCKEN1, and the full enable pulse PUL3 of the clock-enable signal SCKEN3 is delayed from the full enable pulse PUL2 of the clock-enable signal SCKEN2. Through the operations of the clock gating circuits CGA˜CGD in response to the clock-enable signals SCKEN0˜SCKEN3, the clock signals of the clock signals CLK_P0˜CLK_P3 also occur successively, and, thus, the scan paths for the scan groups G10˜G13 are activated successively. Referring to FIG. 3, in response to the timing of the clock-enable signals SCKEN0˜SCKEN3, the clock pulses of the clock signals CLK_P0˜CLK_P3 are not overlapped. In details, the clock pulse of the clock signal CLK_P1 is delayed from the clock pulse of the clock signal CLK_P0, the clock pulse of the clock signal CLK_P2 is delayed from the clock pulse of the clock signal CLK_P1, and the clock pulse of the clock signal CLK_P3 is delayed from the clock pulse of the clock signal CLK_P2. Thus, the scan paths for the scan groups G10˜G13 are not activated simultaneously due to the timing of the clock signals CLK_P0˜CLK_P3.

Referring to FIG. 3, after the clock pulse of the last clock signal CLK_P3 occurs in the scan shift cycle P_scan-shift, the scan chain circuit 1 will enter one following scan capture cycle P_scan-capcure, and the enable pulses of the clock-enable signals SCKEN0˜SCKEN3 occur simultaneously for the scan capture cycle P_scan-capcure. Through the operations of the clock gating circuits CGA˜CGD in response to the clock-enable signals SCKEN0˜SCKEN3, the clock signals of the clock signals CLK_P0˜CLK_P3 occur simultaneously during the scan capture cycle P_scan-capcure.

According to the embodiment, when the scan chain circuit 1 operates in the function mode, the clock-enable signals SCKEN0˜SCKEN3 are kept at a high voltage level.

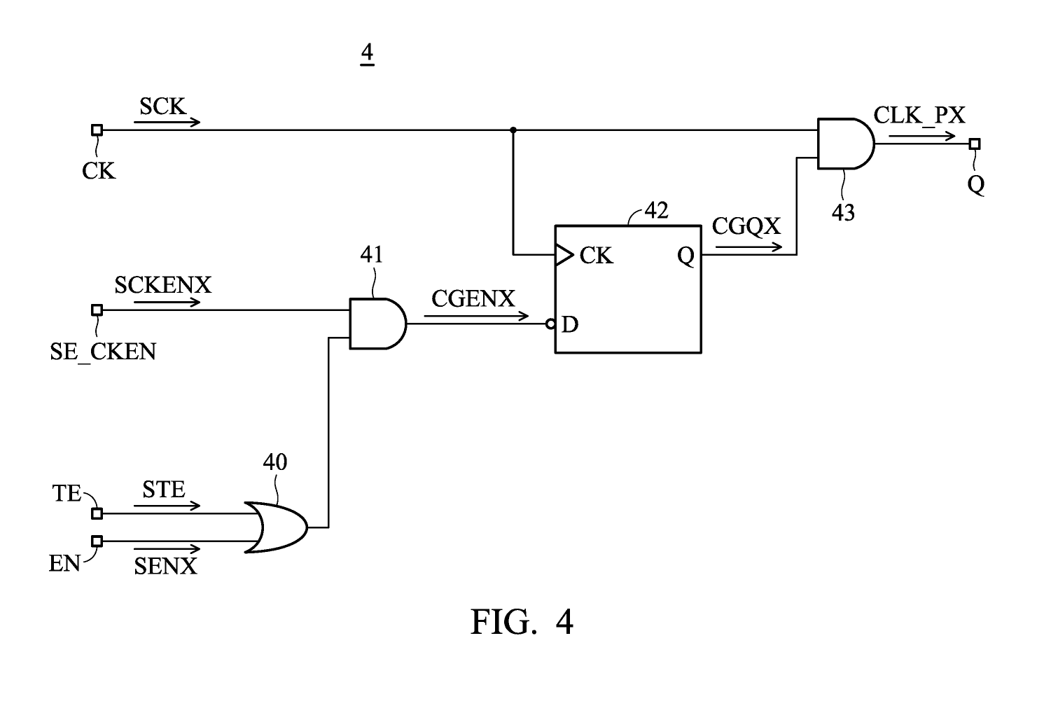

FIG. 4 shows one exemplary embodiment of a clock gating circuit. Referring to FIG. 4, a clock gating circuit 4 is provided. In the embodiment, each of the clock gating circuits CGA˜CGD can be implemented by the clock gating circuit 4. Thus, in FIG. 4, the reference labels “SCKENX”, “SENX”, “CGENX”, “CGQX”, and “CLK_PX” are the signals for one of the clock gating circuits CGA˜CGD, wherein the sign “X” is 0, 1, 2, or 3 respectively for the clock gating circuit CGA, CGB, CGC, or CGD. Referring to FIG. 4 the clock gating circuit 4 comprises an OR gate 40, AND gates 41 and 43, and a latch circuit 42. One input terminal of the OR gate 40 is coupled to the test-enable terminal TE to receive the test-enable signal STE, and the other input terminal thereof is coupled to the gating enable terminal EN to receive the corresponding gating enable signal SENX. One input terminal of the AND gate 41 is coupled to the clock-enable terminal SE_CKEN to receive the corresponding clock-enable signal SCKENX, the other input terminal thereof is coupled to the output terminal of the OR gate 41. The output terminal of the AND gate 41 outputs a corresponding enable signal CGENX. The latch 42 is a negative-edge triggered latch. The input terminal D of the latch circuit 42 is coupled to the output terminal of the AND gate 41 to receive the corresponding enable signal CGENX, the clock terminal CK thereof is coupled to the clock-in terminal CK to receive the reference clock signal SCK, and the output terminal Q thereof outputs a corresponding gating output signal CGQX. One input terminal of the AND gate 43 is coupled to the clock-in terminal CK to receive the reference clock signal SCK, the other input terminal thereof is coupled to the output terminal Q of the D flip-flop, and the output terminal thereof outputs the corresponding clock signal CLK_PX to the corresponding clock-out terminal Q.

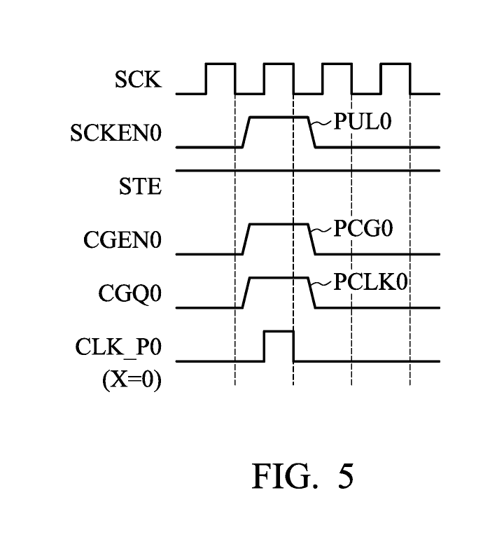

FIG. 5 shows the timing of the main signals of the clock gating circuit 4 during one scan shift cycle of the scan mode. In the following, the signals SCK, SCKEN0, STE, CGEN0, CGQ0, and the CLK_P0 of the clock gating circuit CGA is taken as an example, that is, the sign “X” in FIG. 4 is 0. During the scan shift cycle, the test-enable signal STE is kept at a high voltage level. Through the logic operation of the OR gate 40, the signal at the output terminal of the OR gate 40 is at a high voltage level no matter what the voltage level of the gating enable signal SEN0 is. The AND gate 41 generates the enable signal CGEN0 with a pulse PCG0 in response to the enable pulse PUL0 of the clock-enable signal SCKEN0. The latch 43 latches the enable signal CGEN0 in response to the falling edges of the reference clock signal SCK to generate the gating output signal CGQ0. Then, the AND gate 43 performs an AND logic operation to generate the clock signal CLK_P0 with one clock pulse PCLK0 according to the reference clock signal SCK and the gating output signal CGQ0. The operations of the other clock gating circuits CGB˜CGD are similar to the above operation of the clock gating circuit CGA, and, thus, the related description is omitted here.

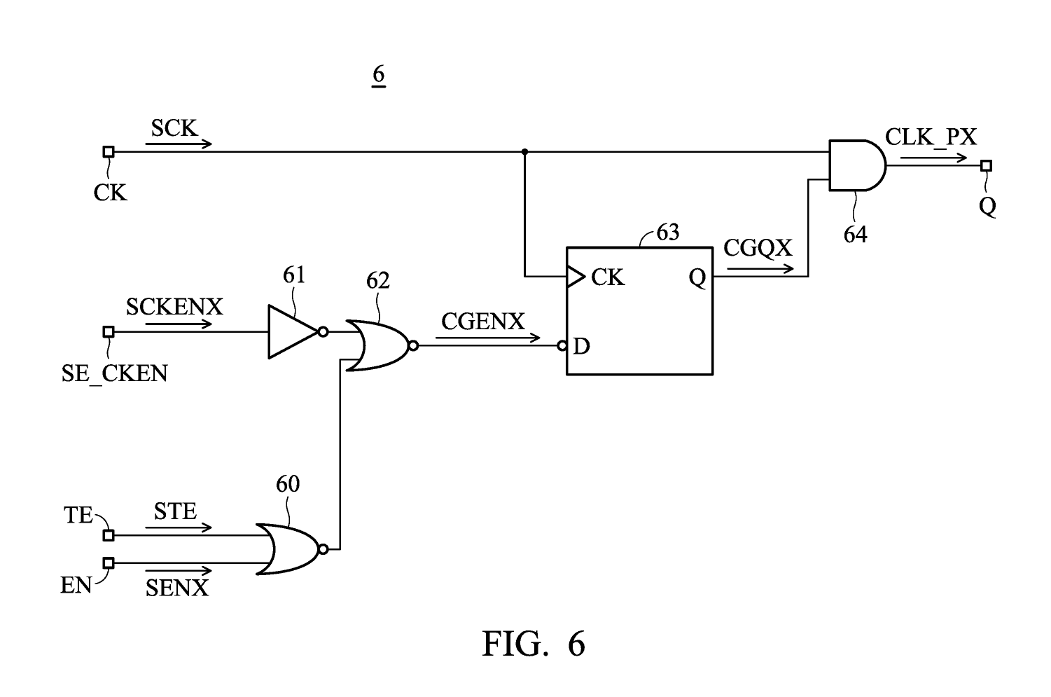

FIG. 6 shows another exemplary embodiment of a clock gating circuit. Referring to FIG. 6, a clock gating circuit 6 is provided. In the embodiment, each of the clock gating circuits CGA˜CGD can be implemented by the clock gating circuit 6. Thus, in FIG. 6, the reference labels “SCKENX”, “SENX”, “CGENX”, “CGQX”, and “CLK_PX” are the signals for one of the clock gating circuits CGA˜CGD, wherein the sign “X” is 0, 1, 2, or 3 respectively for the clock gating circuit CGA, CGB, CGC, or CGD. Referring to FIG. 6 the clock gating circuit 4 comprises OR gates 60 and 62, an inverter 61, a latch circuit 63, and an AND gate 64. One input terminal of the NOR gate 60 is coupled to the test-enable terminal TE to receive the test-enable signal STE, and the other input terminal thereof is coupled to the gating enable terminal EN to receive the corresponding gating enable signal SENX. The input terminal of the inverter 61 is couple to the clock-enable terminal SE_CKEN to receive the corresponding clock-enable signal SCKENX, One input terminal of the NOR gate 62 is coupled to the output terminal of the inverter 61, the other input terminal thereof is coupled to the output terminal of the NOR gate 60. The output terminal of the NOR 62 outputs a corresponding enable signal CGENX. The latch 63 is a negative-edge triggered latch. The input terminal D of the latch circuit 63 is coupled to the output terminal of the NOR 62 to receive the corresponding enable signal CGENX, the clock terminal CK thereof is coupled to the clock-in terminal CK to receive the reference clock signal SCK, and the output terminal Q thereof outputs a corresponding gating output signal CGQX. One input terminal of the AND gate 64 is coupled to the clock-in terminal CK to receive the reference clock signal SCK, the other input terminal thereof is coupled to the output terminal Q of the D flip-flop, and the output terminal thereof outputs the corresponding clock signal CLK_PX to the corresponding clock-out terminal Q.

The operation of the clock gating circuit 6 is similar to the operation of the clock gating circuit 4. In the embodiment of FIG. 6, the NOR gates 60 and 62 and the inverter 61 form an equivalent circuit of the circuit composed by the OR gate 40 and the AND gate 41 of FIG. 4. Thus, the timing of the main signals of the clock gating circuit 6 is the same as the timing of the main signals of the clock gating circuit 4, for example, as shown in FIG. 5.

According to the above embodiments, there is only one clock path composed by the multiplexer 20 and the buffers 21 for the function clock signal func_clock and the scan clock signal scan_clock. When the scan chain circuit 1 operates in each scan shift cycle of the test mode, the scan groups G10˜G13 are not activated simultaneously, which avoid occurrence of high peak currents. Moreover, when the scan chain circuit 1 operates in the function mode, since all the scan flip-flops receive the same reference clock signal SCK (that is the function clock signal func_clock) through the same clock path, so that there is no clock skew induced by several clock paths, and the error in the operation scan flip-flops, which is caused by clock skew, is prevented.

While the invention has been described by way of example and in terms of the preferred embodiments, it is to be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A scan chain circuit comprising:
a first scan flip-flop having a data-in terminal, a scan-in terminal, a clock terminal receiving a first clock signal, and a data-out terminal;
a second scan flip-flop having a data-in terminal coupled to the data-out terminal of the first scan flip-flop, a scan-in terminal, a clock terminal receiving a second clock signal, and a data-out terminal; and
a clock generator receiving a function clock signal, a scan clock signal, a first clock-enable signal, a second clock-enable signal, and a test-enable signal indicating whether the scan chain circuit is in a test mode,
wherein during a scan shift cycle of the test mode, an enable pulse of the second clock-enable signal is delayed from an enable pulse of the first clock-enable signal;
wherein the clock generator generates the first clock signal according to the scan clock signal and the first clock-enable signal, and further generates the second clock signal according to the scan clock signal and the second clock-enable signal.

2. The scan chain circuit as claimed in claim 1, wherein during the scan shift cycle of the test mode, a clock pulse of the second clock signal is delayed from a clock pulse of the first clock signal, and the clock pulse of the first clock signal does not overlap the clock pulse of the second clock signal.

3. The scan chain circuit as claimed in claim 1, further comprising:
a third scan flip-flop having a data-in terminal, a scan-in terminal coupled to the data-output terminal of the first scan flip-flop, a clock terminal receiving the first clock signal, and a data-out terminal; and
a fourth scan flip-flop having a data-in terminal, a scan-in terminal coupled to the data-output terminal of the second scan flip-flop, a clock terminal receiving the second clock signal, and a data-out terminal.

4. The scan chain circuit as claimed in claim 1, wherein the clock generator comprises:
a multiplexer having a first input terminal receiving the function clock signal, a second input terminal receiving the scan clock signal and controlled by the test-enable signal to transmit the function clock signal or the scan clock signal to serve as a reference clock signal;
a first clock gating circuit having a clock-in terminal receiving the reference clock signal, a clock-enable terminal receiving the first clock-enable signal, a gating enable terminal receiving a first gating enable signal, and a test-enable terminal receiving the test-enable signal, and a clock-out terminal outputting the first clock signal; and
a second clock gating circuit having a clock-in terminal receiving the reference clock signal, a clock-enable terminal receiving the second clock-enable signal, a gating enable terminal receiving a second gating enable signal, and a test-enable terminal receiving the test-enable signal, and a clock-out terminal outputting the second clock signal,
wherein in the test mode, the multiplexer transmits the scan clock signal to serve as the reference clock signal, the first clock gating circuit generates the first clock signal according to the reference clock signal and the first clock-enable signal, and the second gating circuit generates the second clock signal according to the reference clock signal and the second clock-enable signal, and
wherein a clock pulse of the second clock signal is delayed from a clock pulse of the first clock signal.

5. The scan chain circuit claimed in claim 4, wherein each of the first clock gating circuit and the second clock gating circuit comprises:
an OR gate having a first input terminal coupled to the corresponding test-enable terminal, a second input terminal coupled to the corresponding clock-gate enable terminal, and an output terminal;
a first AND gate having a first input terminal coupled to the corresponding clock-enable terminal, a second input terminal coupled to the output terminal of the OR gate, and an output terminal;
a latch circuit having an input terminal coupled to the output terminal of the first AND gate, a clock terminal receiving the reference clock signal, and an output terminal, wherein the latch is a negative-edge triggered latch; and
a second AND gate having a first input terminal receiving the reference clock signal, a second input terminal coupled to the output terminal of the latch circuit, and an output terminal coupled to the corresponding clock-out terminal.

6. The scan chain circuit claimed in claim 5, wherein in the test mode, the test-enable is at a high voltage level.

7. The scan chain circuit claimed in claim 4, wherein each of the first clock gating circuit and the second clock gating circuit comprises:
a first NOR gate having a first input terminal coupled to the corresponding test-enable terminal, a second input terminal coupled to the corresponding clock-gate enable terminal, and an output terminal;
an inverter having an input terminal coupled to the corresponding clock-enable terminal and an output terminal;
a second NOR gate having a first input terminal coupled to the output terminal of the inverter, a second input terminal coupled to the output terminal of the OR gate, and an output terminal;
a latch circuit having an input terminal coupled to the output terminal of the first AND gate, a clock terminal receiving the reference clock signal, and an output terminal, wherein the latch is a negative-edge triggered latch; and
an AND gate having a first input terminal receiving the reference clock signal, a second input terminal coupled to the output terminal of the latch circuit, and an output terminal coupled to the corresponding clock-out terminal.

8. The scan chain circuit claimed in claim 7, wherein in the test mode, the test-enable is at a high voltage level.

9. A scan chain circuit comprising:
a multiplexer having a first input terminal receiving a function clock signal, a second input terminal receiving a scan clock signal and controlled by a test-enable signal to transmit the function clock signal or the scan clock signal to serve as a reference clock signal, wherein the test-enable signal indicates whether the scan chain circuit is in a test mode;
a first clock gating circuit having a clock-in terminal receiving the reference clock signal, a clock-enable terminal receiving a first clock-enable signal, a gating enable terminal receiving a first gating enable signal, and a test-enable terminal receiving the test-enable signal, and a clock-out terminal outputting a first clock signal;
a second clock gating circuit having a clock-in terminal receiving the reference clock signal, a clock-enable terminal receiving a second clock-enable signal, a gating enable terminal receiving a second gating enable signal, and a test-enable terminal receiving the test-enable signal, and a clock-out terminal outputting a second clock signal,
a first scan flip-flop having a data-in terminal, a scan-in terminal, a clock terminal receiving the first clock signal, and a data-out terminal; and
a second scan flip-flop having a data-in terminal coupled to the data-out terminal of the first scan flip-flop, a scan-in terminal, a clock terminal receiving the second clock signal, and a data-out terminal.

10. The scan chain circuit as claimed in claim 9, wherein during a scan shift cycle of the test mode, a clock pulse of the second clock signal is delayed from a clock pulse of the first clock signal, and the clock pulse of the first clock signal does not overlap the clock pulse of the second clock signal.

11. The scan chain circuit as claimed in claim 10, wherein during the scan shift cycle of the test mode, the multiplexer transmits the scan clock signal to serve as the reference clock signal, and an enable pulse of the second clock-enable signal is delayed from an enable pulse of the first clock-enable signal.

12. The scan chain circuit as claimed in claim 9, further comprising:
a third scan flip-flop having a data-in terminal, a scan-in terminal coupled to the data-output terminal of the first scan flip-flop, a clock terminal receiving the first clock signal, and a data-out terminal; and
a fourth scan flip-flop having a data-in terminal, a scan-in terminal coupled to the data-output terminal of the second scan flip-flop, a clock terminal receiving the second clock signal, and a data-out terminal.

13. The scan chain circuit claimed in claim 9, wherein each of the first clock gating circuit and the second clock gating circuit comprises:
an OR gate having a first input terminal coupled to the corresponding test-enable terminal, a second input terminal coupled to the corresponding clock-gate enable terminal, and an output terminal;
a first AND gate having a first input terminal coupled to the corresponding clock-enable terminal, a second input terminal coupled to the output terminal of the OR gate, and an output terminal;
a latch circuit having an input terminal coupled to the output terminal of the first AND gate, a clock terminal receiving the reference clock signal, and an output terminal, wherein the latch is a negative-edge triggered latch; and
a second AND gate having a first input terminal receiving the reference clock signal, a second input terminal coupled to the output terminal of the latch circuit, and an output terminal coupled to the corresponding clock-out terminal.

14. The scan chain circuit claimed in claim 13, wherein during a scan shift cycle of the test mode, an enable pulse of the second clock-enable signal is delayed from an enable pulse of the first clock-enable signal, and the test-enable is at a high voltage level.

15. The scan chain circuit claimed in claim 9, wherein each of the first clock gating circuit and the second clock gating circuit comprises:
a first NOR gate having a first input terminal coupled to the corresponding test-enable terminal, a second input terminal coupled to the corresponding clock-gate enable terminal, and an output terminal;
an inverter having an input terminal coupled to the corresponding clock-enable terminal and an output terminal;
a second NOR gate having a first input terminal coupled to the output terminal of the inverter, a second input terminal coupled to the output terminal of the OR gate, and an output terminal;
a latch circuit having an input terminal coupled to the output terminal of the first AND gate, a clock terminal receiving the reference clock signal, and an output terminal, wherein the latch is a negative-edge triggered latch; and
an AND gate having a first input terminal receiving the reference clock signal, a second input terminal coupled to the output terminal of the latch circuit, and an output terminal coupled to the corresponding clock-out terminal.

16. The scan chain circuit claimed in claim 15, wherein during a scan shift cycle of the test mode, an enable pulse of the second clock-enable signal is delayed from an enable pulse of the first clock-enable signal, and the test-enable is at a high voltage level.
